(19) United States
(12) Patent Application Publication
(10) Pub. No.: US 2013/0267062 A1
(43) Pub. Date: Oct. 10, 2013

(54) Dispensing Tool

(71) Applicants: Andreas Poerrer, Regensburg (DE); Benjamin Reichert, Lappersdorf (DE)

(72) Inventors: Andreas Poerrer, Regensburg (DE); Benjamin Reichert, Lappersdorf (DE)

(73) Assignee: INFINEON TECHNOLOGIES AG, Neubiberg (DE)

(21) Appl. No.: 13/440,341

(22) Filed: Apr. 5, 2012

(51) Int. Cl. H01L 21/50; B67D 7/30

(52) U.S. Cl. 438/106; 222/14; 257/E21.499

(57) ABSTRACT

A dispensing tool includes a dispensing outlet for depositing a specific amount of a mounting material on a carrier when the dispensing outlet is at a predetermined dispensing distance from the carrier. The dispensing tool also includes a protrusion element protruding past the dispensing outlet by spanning the dispensing distance between dispensing outlet and carrier during dispensing.

### TECHNICAL FIELD

The invention relates to a dispensing tool, for example to a dispensing tool for dispensing a mounting material for mounting one or more semiconductor chips onto a carrier. The invention relates further to a method for the use of such a tool.

### BACKGROUND

For mounting processes related, for example, to a mounting of semiconductor chips onto a carrier, a mounting material may have to be provided onto a surface of the carrier. The mounting material can include, for instance, solder material and/or adhesive material. A dispensing device (also termed ‘dispenser’ hereinbelow for short) can be provided for this purpose, which has to be suitably configured for providing a desired amount of mounting material to the carrier surface. In case of either an excess or deficit of mounting material, malfunctions of the corresponding semiconductor device can result.

### SUMMARY OF THE INVENTION

According to an embodiment, a dispensing tool is provided. A dispensing outlet is used for depositing a specific amount of the mounting material on a carrier when the dispensing outlet is at a predetermined dispensing distance from the carrier. A protrusion element protrudes over the dispensing outlet by spanning the dispensing distance between dispensing outlet and carrier during dispensing.

### BRIEF DESCRIPTION OF THE DRAWINGS

The accompanying drawings are included to provide a thorough understanding of various embodiments and are incorporated in and constitute a part of this specification. The drawings illustrate different embodiments and together with the description serve to explain miscellaneous aspects thereof.

In the figures and the description like reference numerals are generally utilized to refer to like elements throughout. It is to be noted that the various elements and structures shown in the figures are not necessarily drawn to scale.

FIG. 1, which includes FIGS. 1A, 1B and 1C, schematically illustrates an exemplary embodiment of a dispensing tool;

FIGS. 2A to 2E schematically illustrate an exemplary embodiment of a dispensing tool in a side view in different operational situations and from below, and illustrate operational results of the tool;

FIGS. 3A to 3D schematically illustrate bottom views on various exemplary embodiments of dispensing heads;

FIG. 4 illustrates an exemplary embodiment of a kit comprising two dispensing heads in a schematic side view; and

FIG. 5 illustrates an exemplary embodiment of the method of use of a dispensing tool.

### DETAILED DESCRIPTION OF ILLUSTRATIVE EMBODIMENTS

In the following description, for purposes of explanation and not limitation, by reference to the accompanying drawings, various embodiments are set forth including many specific details thereof in order to provide a thorough understanding of the current invention. It is to be understood that other embodiments, which differ in one or more of these specific details, can be practiced without departing from the scope of the present invention. Accordingly, the following description is intended for illustrative, non-limiting purposes only, and the scope of the present invention shall be defined by the appended claims.

It will further be appreciated that the features of the various exemplary embodiments described herein can be combined with each other, unless specifically noted otherwise.

Carriers as referred to herein may be of any material, size, and shape. For example, a carrier may be made of one or more metals or metal alloys, for example, copper, copper alloys, aluminum, aluminum alloys, etc. Additionally or alternatively a carrier may comprise one or more ceramic materials, such as aluminum oxide. One or more portions of a carrier may be electrically conductive, or can be electrically insulating. An insulating carrier body can, for example, be coated or covered with a conductive layer, a (structured) conductive plate, etc. According to various embodiments, a carrier can comprise one or more leadframes, wafer substrates, etc.

Semiconductor elements may be mounted on a carrier, or may be provided for being mounted on a carrier. Such elements can comprise, for example, passive elements such as resistors or capacitors, and can comprise active elements such as diodes or transistors, and can comprise integrated circuits, semiconductor chips, etc. More generally, the term ‘semiconductor elements’ can comprise any element with at least one electrical, thermal and/or mechanical functionality in the semiconductor field, which can include, for example, elements such as spacers or cooling elements including heat sinks or parts thereof, although such elements may comprise other materials besides semiconducting materials, such as insulating materials or conducting materials, or may even be devoid of semiconducting material.

Mounting materials are discussed herein which are employed for mounting semiconductor elements onto a carrier. A mounting material can generally be provided in the form of a paste, a gel, or other viscous form suitable for deposition by a dispenser onto a carrier. Such mounting materials can comprise, for example, one or both of solder materials and adhesive materials. A solder material can comprise metal alloys composed, for example, from one or more of the following materials: SnPb, SnAg, SnAgCu, SnAgCuNi, SnAu, SnCu, and SnBi. An adhesive material can comprise one or more electrically conductive adhesive materials, one or more electrically insulating adhesive materials, or both. An adhesive can be based, for example, on an epoxy resin. An adhesive can comprise compounds such as gold, silver, nickel or copper for achieving a desired degree of electrical conductivity.

Embodiments of dispensing tools and related aspects are described herein. A dispensing tool may form an integrated or attachable part of a dispenser, or may be identical to a dispenser. The term ‘dispenser’ may generally cover any device or article suitable for applying mounting material to a carrier. For example, a dispenser may be configured to apply or deposit one or more dots or spots of mounting material to a carrier either sequentially and/or in parallel. As an example, a dispenser with a single dispensing outlet such as an open tip of a canula or hollow needle may apply a single dot of solder or adhesive at a time, while a dispenser with multiple dispensing outlets may correspondingly deposit multiple dots at a time. A dispenser can be adapted for one or more general dispensing techniques such as, for example, vacuum dispensing or depositing, vacuum-push depositing, etc.

A dispensing outlet can comprise an opening or port, but can also comprise multiple openings or ports, such as, for example, a mesh-like or meshed opening. The dispensing outlet can comprise elements such as nozzles, valves, heating elements, sensor elements, and/or other or further elements for controlling (e.g., sensing) a dispensing of the mounting material.

A dispensing tool for dispensing can, for example, comprise a dispensing head (or ‘dispenser head’ or ‘dosing head’) generally adapted for dispensing and a dispensing body generally adapted for attachment to a dispenser for example via an engagement technique such as threading, clipping, screwing, etc.

The dispensing tool or its dispensing head may comprise a dispensing outlet for depositing mounting material on a carrier. A non-limiting exemplary embodiment can comprise a dispensing head providing a base or socket, which supports one or more canulas, hollow needles or other tube-like structures. Each of these one or more structures can comprise at least one dispensing outlet; an open tip of a canula or needle is but one implementation of a dispensing outlet.

Various configurations of dispensers or dispensing tools provide for a dispensing of separate dots or spots of mounting material, while according to other configurations the deposited dots can overlap each other on the carrier; for example, a sequence or chain of dots may form a continuous line or path of mounting material extending over the carrier.

Dot parameters such as an amount of mounting material deposited per dot, a diameter or height of a dot, etc., are affected by various conditions including a pressure applied to the mounting material in the dispenser, a viscosity of the mounting material, a size of the dispensing outlet, environmental pressure and temperature conditions, etc. As but one example, a viscosity of the mounting material may be controlled by a temperature of the mounting material, a temperature of the carrier, environmental humidity conditions, etc.

The dispensing distance between dispensing outlet and carrier can contribute to controlling the amount of deposited material. For example, in a vacuum-push configuration with given viscosity, the material already set free from a dispensing outlet and residing on the carrier may limit the amount of further material which can escape the dispenser and may in this way limit the dot size and/or other parameters. In the circumstantial case of a larger than appropriate distance between dispensing outlet and carrier surface, too large a dot may be dispensed. In the circumstantial case of a dispensing outlet in a smaller than appropriate distance from the carrier surface, or even touching the carrier surface, too small a dot may be dispensed, or the deposition of a dot can even be prevented altogether. In case a deposition of mounting material is entirely prohibited at one deposition location, this could result in too large an amount of mounting material being deposited on a subsequent deposition location.

A desired value of a dispensing distance can be calculated as the distance between dispensing outlet and carrier during dispensing or dot deposition. According to various embodiments, a desired dispensing distance can be calculated as a distance of the dispensing outlet from a support for the carrier. According to one example, a desired dispensing distance can be calculated as a distance of the dispensing outlet from a surface of a work bench for supporting the carrier. These or other calculations can, for example, involve the assumptions of the carrier being of a particular predetermined thickness and of the carrier being entirely flat above the support (such that the dispensing distance is independent of dispenser position in an x-y-plane parallel to the carrier surface).

According to various embodiments, a dispensing distance which has been calculated or otherwise pre-determined in part or entirely for a particular dispenser or dispensing tool can be programmed for the dispenser. As a result, the dispenser is then accordingly controlled during an operation thereof.

Protrusion elements are discussed herein. A protrusion element as understood herein can be an element suitable to span a dispensing distance between a dispensing outlet and a carrier surface. A protrusion element can be provided at a dispensing tool (or a dispenser), and can include one or more parts, portions, sections or generally one or more structures or structural elements of, at, on, or in association with a dispensing tool. Various embodiments of protrusion elements comprise one or more pins, downholders, distance pieces, spacers, distance bars, etc.

A protrusion element can form an integral part of a dispensing tool, for example, of a dispensing head, or can be attachable to the dispensing tool. A protrusion element can be fixed with respect to other structural elements of the dispensing tool, e.g., a dispensing head or a dispensing outlet, and may in this way implement a fixed or constant dispensing distance. A protrusion element can be configurable two or more different dispensing distances and can, for example, be adjustable in a continuous way or in discrete steps. As but one non-limiting example, a protrusion element can be formed integral with a dispensing tool and can at the same time be adjustable if provided, for example, as an expandable element, a pivotable element, and/or including telescopic joints or hinges.

A protrusion element can come into contact with a carrier. According to various embodiments, the protrusion element may function as a downholder holding down a warped or bent carrier into its desirable flat position. The protrusion element may therefore be adapted to mechanically withstand a contact with a carrier. One or more parts of the protrusion element can be prepared for a contact with the carrier and can, for example, be specifically adapted to avoid damaging the carrier. For example, a potentially contacting portion of a protrusion element can comprise a soft and/or flat surface without ripples, ridges, fins, etc., and/or can be made of or coated with an appropriate material. Additionally or alternatively, a potentially contacting portion of a protrusion element can be adapted to avoid a sticking of mounting material and can comprise, for example, an anti-stick coating in this respect, which may include a coating with, e.g., PTFE.

A protrusion element can be arranged fixedly or rigidly with respect to a dispensing outlet either permanently or during a dispensing operation. A protrusion element may be permanently attached to a dispensing head or other part of a dispensing tool, for example, by providing an appropriate bore-hole into which a pin or similar structure is fitted. A protrusion element can be manually and/or automatically adjustable to span the dispensing distance, for example, by shifting, pivoting and/or telescoping action, and can, for example, be adjustable to not extend over the dispensing outlet in a non-operational phase. According to a non-limiting specific example, in case a dispensing head comprises one or more needles, the protrusion element can be implemented as a further needle and can be configurable to have a length longer than the length of the dispensing needles during dispensing operation and can be configurable to have the same length as the dispensing needles during non-operation.

A kit for use with a dispenser can comprise multiple dispensing heads. For example, a set of dispensing heads can comprise multiple dispensing heads with varying properties, wherein the heads can be adapted for a different number of dots to be applied in parallel during a dispensing operation, for different geometries of multiple dots to be applied in parallel, for different dispensing distances, etc. One or more of the dispensing heads of the kit or set can be selected accordingly and operatively attached to the dispenser.

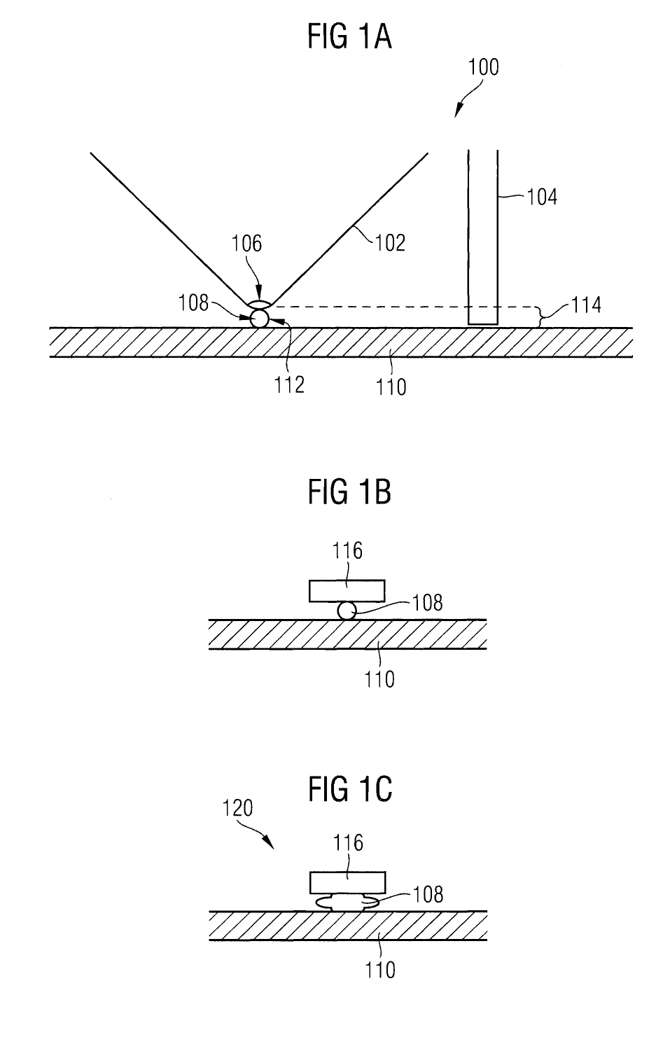

FIG. 1A schematically illustrates an embodiment 100 of a dispensing tool comprising a dispensing head 102 and a protrusion element 104. The dispensing head 102 comprises a dispensing outlet 106. The dispensing tool 100 is adapted for dispensing mounting material 108 onto a carrier 110. The mounting material 108 can comprise an adhesive material and/or solder material for mounting a semiconductor chip on the carrier 110.

Referring to a dot or droplet 112 formed by the mounting material 108 during dispensing, the dispenser 100 is adapted for depositing a specific amount of the mounting material 108 on the carrier 110, which includes that the dispensing outlet 106 is at a dispensing distance 114 from the carrier 110 during dispensing. The protrusion element 104 protrudes over the dispensing outlet 106 (in a direction towards the carrier 110) by spanning the dispensing distance 114.

As shown in FIG. 1B, a semiconductor element 116, such as an integrated circuit or power chip, is located over the mounting material 108 and adhered to the carrier 110 by means of the mounting material 108. FIG. 1C shows the semiconductor device 120 that is formed from the semiconductor element 116 and carrier 110.

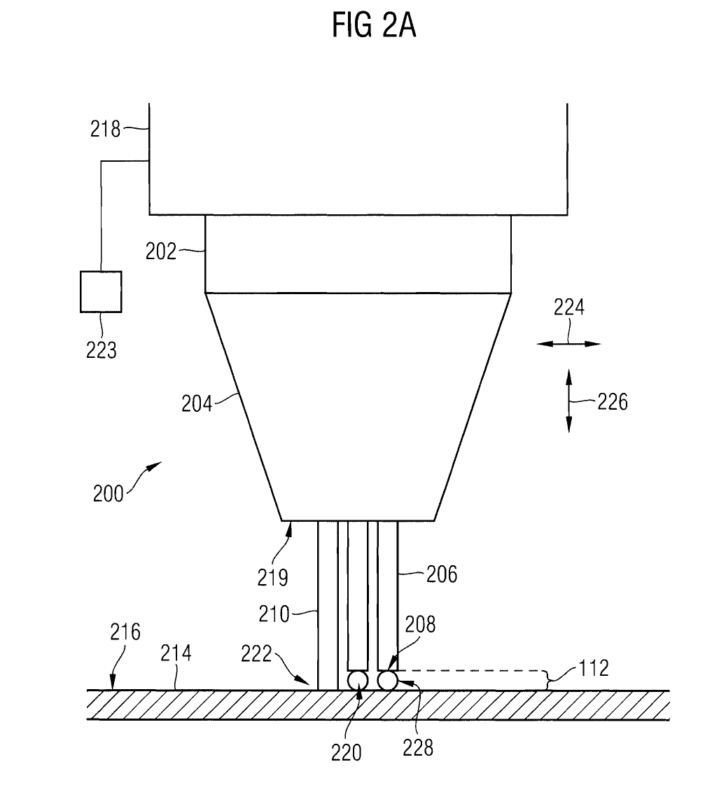

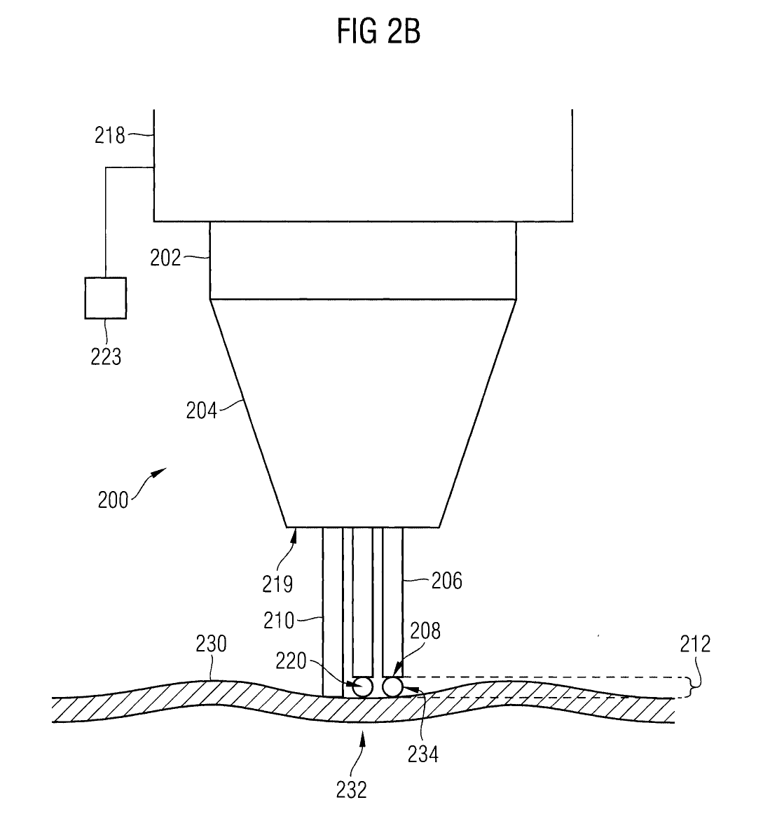

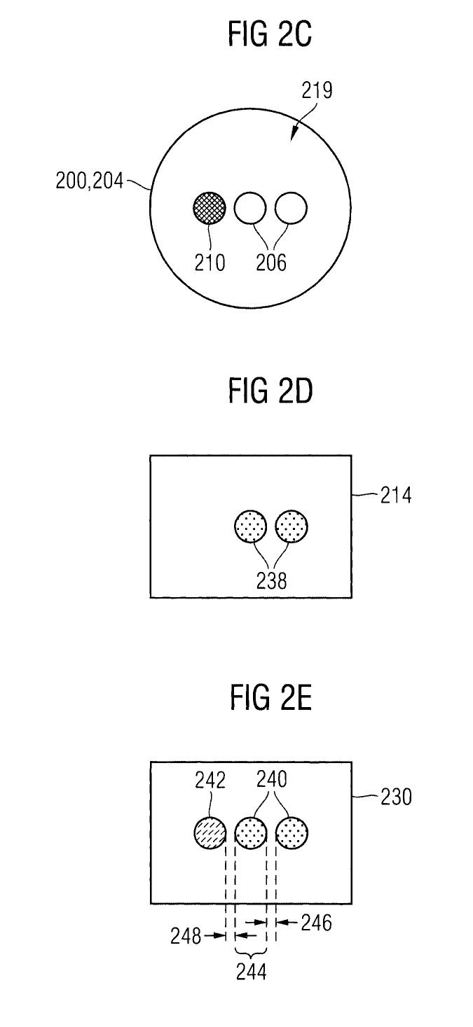

FIG. 2A schematically illustrates an embodiment 200 of a dispensing tool comprising a dispensing tool body 202, a dispensing tool head 204, two dispensing needles 206 with one dispensing outlet 208 on a needle tip of each of the needles 206. The dispensing tool 200 further comprises a protrusion element 210 implemented as a downholder-pin in this exemplary and non-limiting embodiment. The element or pin 210 spans a dispensing distance 212 towards a carrier 214, more precisely a surface 216 thereof, i.e., the pin 210 extends for the dispensing distance over the dispensing outlets 208.

The dispensing tool 200 is adapted for attachment to a schematically indicated dispenser 218. For example, the tool 200 may be attached via its body 202 to dispenser 218 by screwing, snapping, or plugging action. The dispensing needles 206 and pin 210 all are supported on a common base 219 of dispensing head 204. The pin 210 is exemplarily assumed to have a structure similar to the structure of needles 206, except for the lengths of needles 206 and pin 210, respectively, wherein the lengths measured from base 219 differ by the dispensing distance 212. Both needles 206 and pin 210 can, for example, comprise one and the same kind or type of tube-like structure, wherein the needles 206 are configured for passing mounting material 220 therethrough, while pin 210 can be a blind tube, which can be open or closed also at the touchdown 222 on the carrier surface 216. It is assumed that pin 210 can withstand mechanical contact with carrier 214 as illustrated in FIG. 2A and subsequently in FIG. 2B.

In order to deposit mounting material 220 at a desired position on the carrier surface 216, a controller 223 controls dispenser 218 to move in an x-y plane parallel to carrier surface 216 as indicated by arrow 224. During such x-y movement, dispensing head 204 supports pin 210 and needles 206 in a positioning (z-)distance above carrier 214, wherein in particular the distance in z-direction (height above the carrier surface 216 as indicated by arrow 226) between downholder pin 210 and carrier surface 216 can be sufficient to avoid contact which may occur, for example, due to a warping of the carrier 214.

After having reached a desired x-y position, the controller 223 moves dispenser 218 and/or dispensing tool 200 (e.g., head 204) down to a pre-programmed dispense height, which is the situation illustrated in FIG. 2A. The dispense height can be calculated with reference to a (dispenser) reference system and can, for example, be calculated as a height of the dispensing outlets 208 above a support for the carrier 214. In this example, a value for the dispense height can result from a thickness of carrier 214 plus the dispensing distance 212 (with respect to downholder pin 210, the dispense height would only amount to the carrier 214 thickness). Assuming, for example, a perfectly flat carrier 214 and support for the carrier 214, and a constant dispensing distance 212, a dispensing height including the dispensing distance can be programmed as a constant into the controller 223, which may be implemented as hardware, software (including firmware), or both and may be implemented as a stand-alone entity, or as a part of the dispenser 218 or dispensing tool 200, or both. A fast and cost-efficient manufacturing process can result, as the controller 223 may only change z-position between preprogrammed positioning distance and dispensing distance during dispensing operation, without the need for sensing an actual position of the dispensing outlets 208 above carrier surface 216 and corresponding adjustment of z-position.

Referring further to the dispensing situation illustrated in FIG. 2A, when the mounting material 220 is deposited on the carrier surface 216, parameters of resulting dots or droplets 228 such as an amount of material 220, a dot 228 size, etc., can be determined, amongst others, by the dispensing distance 212. As described further with respect to FIG. 2B below, presence of the downholder pin 210 ensures that a minimum distance, i.e., the dispensing distance, is always present between dispensing outlets 208 and carrier 214. This enables a reliable deposition of mounting material, which in turn allows a homogenous and reproducible coating of carriers with the mounting material. The downholder pin 210 is but one implementation of a protrusion element, wherein also other implementations can achieve the above properties.

Exemplary, non-limiting number values are discussed as follows. A length of canulas or needles such as the needles 206 measured from base 219 of dispensing head 204 to the tips/dispensing outlets 208 may generally be in the range of, for example, 1 to 10 millimeters, or 3.5 to 5 millimeters. For dispensing distances in the range of 100 to 300 micrometers, for example around 170 micrometer, the length of pin-like protrusion elements such as downholder pin 210 results accordingly.

FIG. 2B illustrates the dispensing tool 200 in a similar operational configuration as has been described with reference to FIG. 2A. However, in FIG. 2B a carrier 230 is warped, which may be the result of a prior processing including, for example, application of heat. After reaching a desired x-y position 232, dispenser 218 and/or dispensing head 204 move down from the positioning distance to the preprogrammed dispense height or dispensing distance 212. In the situation of FIG. 2B, due to the warping of carrier 230, the downholder pin 210 gets into contact with carrier 230 and presses the carrier 230 locally into a flat position. ‘Locally’ may designate an area on the carrier 230 around the touchdown of the pin 210, wherein the area would include the desired position 232 of the dots 234 of mounting material 220 on the carrier 230. The downholder pin 210 in this way essentially ensures the dispensing distance 212 between the dispensing outlets 208 and carrier 230 at the position 232.

The dispensing tool 200 thus enables that mounting material 220 is deposited in a similar amount and at a desired position in case of a flat carrier as in FIG. 2A, as well as in case of a warped carrier as in FIG. 2B, even in case the carrier 230 would move back into a warped configuration after removal of downholder pin 210. While in the example embodiment 200 the downholder pin 210 is illustrated and discussed as having similar structural properties as the dispenser needles 206, according to other embodiments protrusion elements can be provided which have a higher mechanical stability as, e.g., dispenser needles or canulas, in order to meet with requirements of mechanical stability. Such requirements may include a reliable interaction with bending or warping carriers of given properties over the intended lifetime of a dispensing tool, for example.

It is noted that a result of the interaction of one or more protrusion elements with a warped carrier can comprise that the carrier may (re-)achieve a flattened shape and keep the flat shape after the dispensing operation.

FIG. 2C schematically depicts a bottom view of dispensing tool 200, more precisely a view onto base 219 (see FIGS. 2A, 2B) of dispensing head 204, wherein the needles 206 and downholder pin 210 are arranged in a sequential direction. FIG. 2D illustrates the result of a dispensing action with dispensing tool 200 on carrier 214 of FIG. 2A. The dispenser needles 206 each have deposited a dot 238 of mounting material onto the carrier 214. FIG. 2E illustrates the result of a dispensing action onto the warping carrier 230 of FIG. 2B. Dots 240 have been deposited on carrier 230 in much the same way as for the dots 238 in FIG. 2D. Additionally, due to the pressing interaction of downholder pin 210 with the warping carrier 230, an imprint 242 can be visible on the carrier 230 as a result of a slight damage of, for example, a free surface or a coating of carrier 230.

While in FIG. 2E the imprint 242 of downholder pin 210 is illustrated for the case of the pressing interaction between protrusion element and warped carrier in FIG. 2B, in other cases or embodiments there may be no such imprints visible even in case of a warping carrier, depending on configurational and structural details of the protrusion element and carrier surface. On the other hand, if acceptable, imprints can also be visible for slight interactions between a protrusion element and a flat carrier such as that illustrated in FIG. 2A.

According to some considerations a distance between protrusion element and dispensing outlet should be minimized in order to achieve a desired degree of flatness of a warping carrier at the points of deposition of the mounting material. On the other hand, it can also be considered that in some embodiments a distance between protrusion element and dispensing outlet should be large enough that a contact of the protrusion element with dispensed mounting material can be avoided (setting aside options such as an anti-stick coating for the protrusion element). Design decisions may implement a cost-efficient trade-off between contravening requirements for particular application cases.

The embodiment illustrated in FIGS. 2A to 2E is an example for a working configuration, wherein, with reference to a plane parallel to a carrier surface as illustrated in FIGS. 2D, 2E, a distance between downholder pin 210 to the nearest of the dispenser needles 206 is chosen similar to the distance (pitch size) between the dispenser needles 206.

Referring further to FIG. 2E, non-limiting exemplary number values are given in the following. A canula diameter (for simplicity assumed to be equal to a dot or droplet diameter 244) can be 0.5 millimeter, while a distance between the canulas, i.e., a center-to-center distance, can be 0.9 millimeter, which would result in a droplet-to-droplet separation 246 of 0.4 millimeter. In the case of continued pitch size, the distance 248 between downholder pin and nearest canula can also be 0.4 millimeter. Smaller distance values are also possible; in another exemplary embodiment a canula diameter would also amount to 0.5 millimeter, but a canula distance or separation would only be 0.65 millimeter, which would result in a droplet separation of only 150 micrometer, which can also be the separation between the downholder pin (or other protrusion element) and nearest dispensing outlet.

If small distances between protrusion elements and dispensing outlets have to be established, the potential impact of contacts between protrusion element and mounting material could be minimized by selecting an anti-stick material for the protrusion element and/or an appropriate coating of the protrusion element, for example, with a teflon-like material.

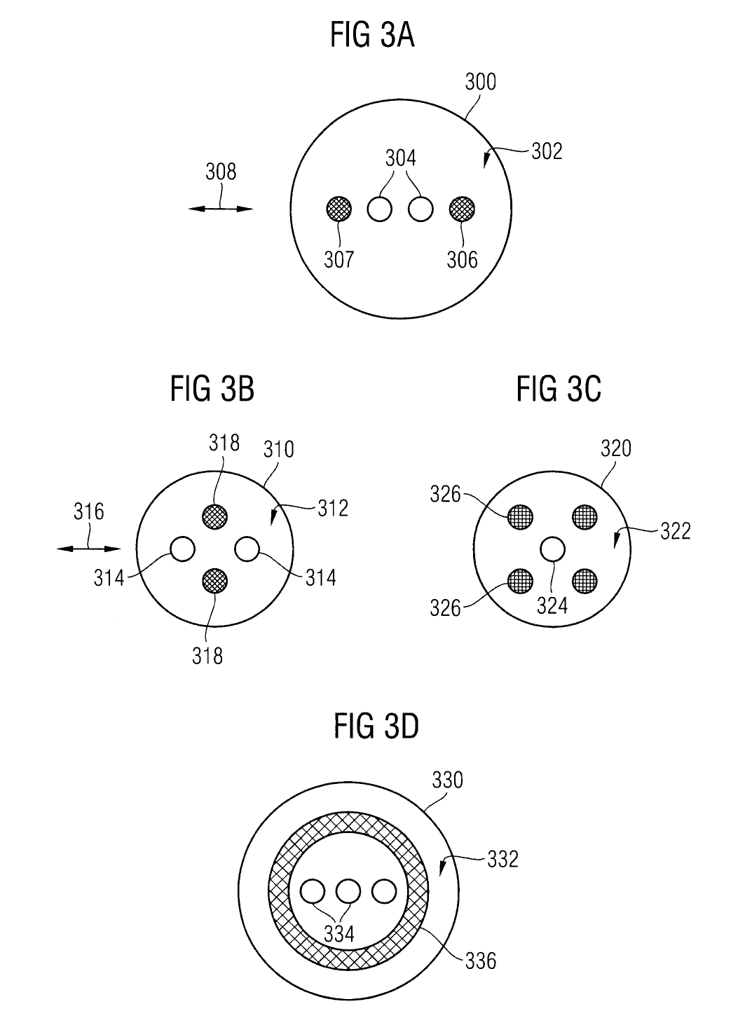

FIGS. 3A to 3E illustrate bottom views onto embodiments of dispensing heads in a way similar to the bottom view of FIG. 2C. Aspects of the embodiments not expressly discussed below may be similar to corresponding aspects of the embodiments discussed with reference to the FIGS. 1 and 2A to 2E or as discussed elsewhere herein.

FIG. 3A shows a base 302 of a dispensing head 300. Similar to dispenser head 204 in FIG. 2C, the dispensing head 300 comprises two canulas 304 for depositing mounting material on a carrier. The dispensing head 300 supports two protrusion elements 306 and 307, wherein each element 306, 307 can be formed as a pin. Assuming an indexing direction along arrow 308, pin 306 would press a warping carrier down in front of the dispensing outlets 304, while pin 307 would press a warping carrier down behind the dispensing outlets 304 (or vice versa).

The combined interaction of pins 306, 307 with a warping carrier could result in a particular degree of flatness of the carrier in an area including the locations of dot deposition of dispensing outlets 304. The degree of flatness can be increased in comparison to using a single downholder pin only. It is to be noted that a degree of flatness depends not only on the number and position of protrusion elements (e.g., downholder pins), but also on other parameters such as thickness and warping of a carrier, the action of other downholder devices provided in association with a carrier support, etc.

FIG. 3B illustrates an alternative configuration wherein a base line 312 of a dispensing head 310 supports two needles or canulas 314 which are accompanied laterally (with reference to an indexing direction 316) by two protrusion elements (downholder pins) 318. FIG. 3C illustrates still another embodiment of a dispensing head 320 with base supporting a single dispensing outlet 324 in the center of a square configuration formed by four downholder pins 326. A further embodiment is shown in FIG. 3D, wherein a dispensing head 330 has a base 332 supporting three dispensing outlets 334 circumvented by an annular protrusion element 336. One or more of the configurations shown in the figures can be selected in order to, for example, minimize a flow of dispensed mounting material on the carrier due to a warping of the carrier during or after a dispensing operation despite a downholding action of one or more protrusion elements.

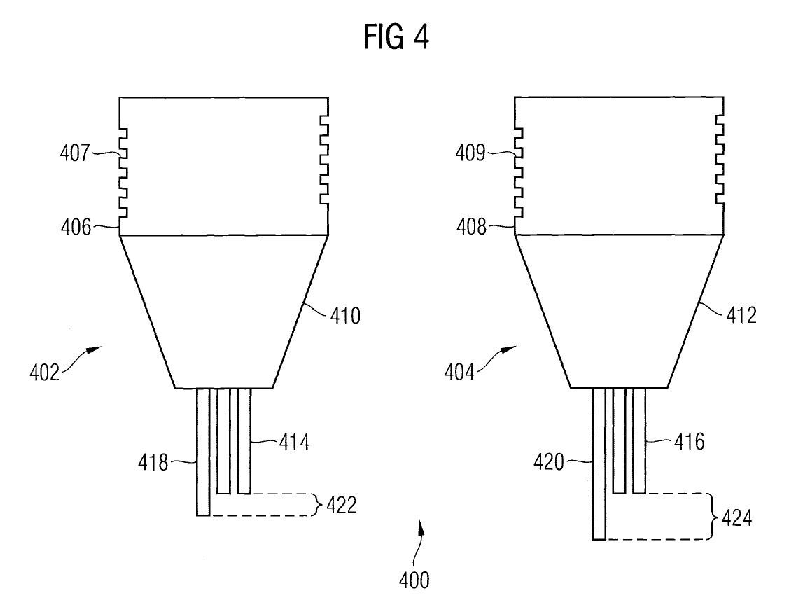

FIG. 4 illustrates an embodiment of a kit 400 comprising at least two dispensing tools 402 and 404. Each of the dispensing tools 402, 404 comprises a body 406, 408 with threads 407, 409 for threading engagement with a dispenser device as well as a dispensing head 410, 412. Each of the dispensing heads 410, 412 supports two canulas 414, 416 and a single pin-like protrusion element 418, 420. The dispensing heads 410, 412 are adapted for different dispensing distances 422, 424, wherein the pin 418 spans the smaller dispensing distance 422, while the pin 420 spans the larger dispensing distance 424 (with reference to the dispensing outlets assumed to be on the tips of the canulas 414, 416). One of the tools 406, 408 would be accordingly selected depending on desired parameters such as, for example, a desired size of deposited dots, an amount of mounting material per dot, etc.

Various embodiments of kits comprise more than two dispensing tools, and comprise, for example, 3, 5, 10 or more tools, wherein the tools may differ in dispensing distance and/or properties such as number of canulas (dispensing outlets), canula diameters, employability for different mounting materials, number of protrusion elements, structure of protrusion elements (e.g., pin-like or annular or other structure), mechanical stability of protrusion elements, etc.

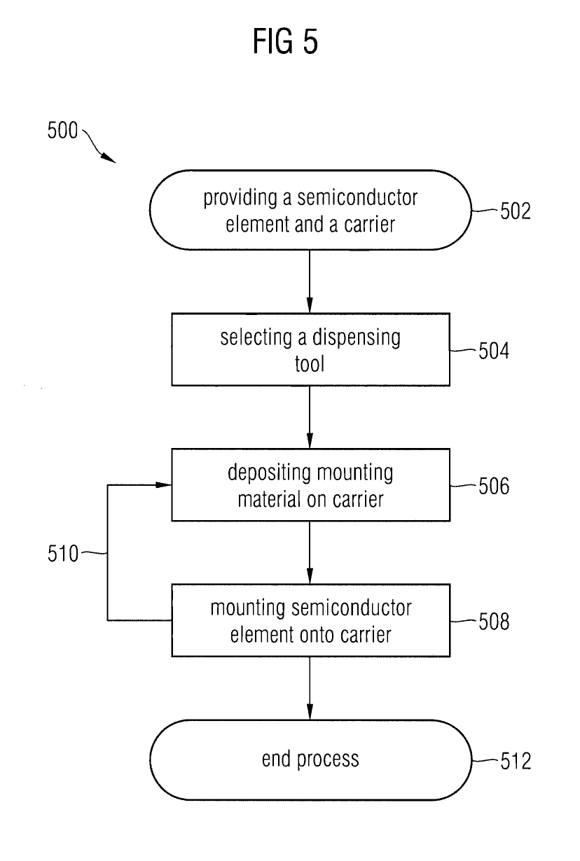

FIG. 5 is a flow diagram illustrating an embodiment 500 of a method for mounting a semiconductor element onto a carrier (502). For example, the method or process 500 may relate to processes on wafer level (Wafer Level Packaging), may relate to processes such as die bonding of dies, pasting processes, etc. Generally, the method 500 may relate to mounting of an integrated circuitry (IC) or a semiconductor chip, wherein the chip may, for example, be a small or thin chip with a thickness of less than 100 micrometer, or less than 60 micrometer, or even less. The carrier may be a leadframe, for example.

While the method 500 is illustrated in FIG. 5 as comprising a particular sequence of steps, it is to be understood that the steps described hereinbelow can be performed in parallel and/or in a different order in other embodiments, wherein also other steps may be performed or steps described below may be omitted.

In step 504, a suitable dispensing tool is selected. For example, one of the tools 402, 404 of kit 400 in FIG. 4 may be selected according to the specifics of a manufacturing process to be performed. In step 506, a specific amount of a mounting material is deposited on a carrier by a dispensing outlet of the selected dispensing tool, when the dispensing outlet is at a predetermined dispensing distance from the carrier. A protrusion element protrudes over the dispensing outlet by spanning the desired dispensing distance between dispensing outlet and carrier during dispensing, thereby ensuring a proper amount of mounting material, dot size, etc. on the carrier even in case of a warped carrier.

In step 508 one or more semiconductor elements such as passive or active semiconductor elements, such as semiconductor chips, are mounted on the carrier by positioning the element or elements on the deposited mounting material, i.e., on the one or more dots or droplets applied in step 506 to the carrier. Step 508 may include or may be followed by further steps of manufacturing a semiconductor device such as further mounting steps, e.g., a hardening or curing or pre-curing of the deposited mounting material, a pressing of the semiconductor element onto the mounting material, a mounting of further elements onto the carrier, an encapsulation of the carrier with elements mounted thereon, a separation of a wafer into dies, etc.

Step 506 may include additional steps such as spanking the deposited mounting material or otherwise preparing or configuring the deposited material for mounting the elements in step 508, including a curing or pre-curing of the material, for example. Moreover, steps 506 and 508 can be performed in repeated sequential order or in parallel for mounting multiple elements onto a carrier, which is indicated by arrow 510. The process 500 ends in step 512, for example with ejecting or discarding the manufactured semiconductor device.

While a particular feature or aspect of an embodiment may have been disclosed with respect to only one or few of several implementations, such feature or aspect may be combined with one or more other features or aspects of the other implementations as may be desired and advantageous for any given or particular application. To the extent that terms such as “include,” “have,” “with,” or variants thereof are used in either the detailed description or the claims, such terms are intended to be inclusive in a manner similar to the term “comprise.” The term “exemplary” is merely meant as referring to an example, rather than a best or optimal example.

While specific embodiments have been illustrated and described herein, it will be appreciated by those of ordinary skill in the art that a variety of alternate and/or equivalent implementations may be substituted for the specific embodiments shown and described without departing from the scope of the present invention. It is intended that the current invention be limited only by the scope of the claims appended herewith.

What is claimed is:

1. A dispensing tool, comprising:
a dispensing outlet configured to deposit a specific amount of a mounting material on a carrier when the dispensing outlet is at a predetermined dispensing distance from the carrier; and
a protrusion element protruding past the dispensing outlet by spanning the dispensing distance between the dispensing outlet and the carrier during dispensing.

2. The dispensing tool of claim 1, wherein the protrusion element is rigidly arranged with respect to the dispensing outlet at least during a dispensing operation of the dispensing tool.

3. The dispensing tool of claim 1, further comprising a dispensing head supporting the dispensing outlet.

4. The dispensing tool of claim 3, wherein the protrusion element is mechanically integrated with the dispensing head.

5. The dispensing tool of claim 1, wherein the protrusion element is adapted for mechanical contact with the carrier.

6. The dispensing tool of claim 5, wherein the protrusion element is adapted for mechanical contact with a metal carrier or a ceramic carrier.

7. The dispensing tool of claim 1, wherein the protrusion element is adapted for downholding the carrier.

8. The dispensing tool of claim 3, wherein the dispensing head comprises one or more canulas, each canula comprising a dispensing outlet at its tip facing towards the carrier.

9. The dispensing tool of claim 1, wherein the protrusion element comprises one or more pins.

10. The dispensing tool of claim 9, wherein the one or more pins are arranged in a symmetric configuration with respect to the dispensing outlet.

11. The dispensing tool of claim 1, wherein the protrusion element is arranged with respect to the dispensing outlet to minimize a flow of dispensed mounting material on the carrier.

12. The dispensing tool of claim 3, wherein the dispensing head provides a common baseline from which one or more canulas and one or more pins protrude.

13. The dispensing tool of claim 9, wherein a pin length equals a canula length plus the dispensing distance.

14. The dispensing tool of claim 9, wherein at least one of the one or more pins comprises a tube structure.

15. The dispensing tool of claim 14, wherein the one or more canulas and the one or more pins comprise one and the same tube structure.

16. The dispensing tool of claim 1, wherein the protrusion element is spaced apart from the dispensing outlet in order to avoid contact with the dispensed mounting material.

17. The dispensing tool of claim 1, further comprising means for moving the dispensing outlet to a preprogrammed distance from a carrier support.

18. The dispensing tool of claim 1, wherein the mounting material comprises solder or adhesive.

19. The dispensing tool of claim 1, wherein the dispensing tool is adapted for pressure pushing the mounting material out of the dispensing outlet under vacuum conditions.

20. A kit for use with a dispenser, the kit comprising:
a dispensing head; and
a protrusion element;
wherein the dispensing head comprises a dispensing outlet for depositing a specific amount of mounting material on a carrier when the dispensing outlet is at a predetermined dispensing distance from the carrier; and
wherein the protrusion element protrudes past the dispensing outlet by spanning the dispensing distance between the dispensing outlet and the carrier during dispensing.

21. The kit of claim 20, wherein the dispensing head is one of a plurality of dispensing heads, wherein each dispensing head has a protrusion element mechanically integrated therewithin, the protrusion elements each adapted for different dispensing distances.

22. A method for making a semiconductor device, the method comprising:
providing a semiconductor element and a carrier;
depositing, by a dispensing outlet of a dispensing tool, a specific amount of a mounting material on the carrier when the dispensing outlet is at a predetermined dispensing distance from the carrier, wherein the dispensing tool includes a protrusion element protruding over the dispensing outlet by spanning the dispensing distance between the dispensing outlet and the carrier during dispensing; and
adhering the semiconductor element to the carrier using the mounting material.

23. The method of claim 22, wherein the dispensing tool comprises multiple dispensing tools, the method further comprising configuring a selected dispensing tool for the predetermined dispensing distance.

24. The method of claim 22, wherein the dispensing tool comprises multiple dispensing heads, each dispensing head comprising a mechanically integrated protrusion element, wherein one of the dispensing heads is adapted for the predetermined dispensing distance.
